(19) United States
(12) Patent Application Publication
(10) Pub. No.: US 2024/0063073 A1
(43) Pub. Date: Feb. 22, 2024

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Naoki YOSHIMATSU, Tokyo (JP); Shintaro ARAKI, Tokyo (JP); Rui KONISHI, Tokyo (JP)

(73) Assignee: Mitsubishi Electric Corporation, Tokyo (JP)

(21) Appl. No.: 18/260,282

(22) PCT Filed: Mar. 25, 2021
(86) PCT No.: PCT/JP2021/012534

§ 371 Date: Jul. 3, 2023

(51) Int. Cl. H01L 23/36; H01L 23/00; H01L 23/49; H01L 23/31; H01L 21/56

(52) U.S. Cl. CPC H01L 23/36; H01L 24/40; H01L 23/49; H01L 23/3121; H01L 24/37; H01L 21/56; H01L 2224/40245; H01L 2224/37011; H01L 2224/84801

(57) ABSTRACT

Provided is a semiconductor device having excellent heat dissipation at low cost. The semiconductor device includes a heat spreader, a semiconductor element, a metal block, a terminal having a plate shape, and a sealing material. The semiconductor element includes a front surface electrode and is mounted on an upper surface of the heat spreader. The metal block includes a bonding surface bonded to the front surface electrode and a heat dissipating surface connected to the upper surface with interposition of the insulating member. The metal block is provided so as to straddle above one side of the semiconductor element. The first end of the terminal is bonded to the metal block. The second end of the terminal is exposed from the sealing material and formed to be connectable to an external circuit. The sealing material seals the heat spreader, the semiconductor element, the metal block, and the first end.

### TECHNICAL FIELD

The present disclosure relates to a semiconductor device and a method of manufacturing a semiconductor device.

### BACKGROUND ART

When the semiconductor element performs a switching operation, heat is generated by internal resistance of the semiconductor element. The heat is released to the cooler through a heat spreader or the like. For example, a semiconductor device described in Patent Document 1 forms a heat dissipation path from a semiconductor element to a cooling body through a heat sink block being a metal body bonded to a front surface of the semiconductor element and an upper side heat sink bonded to the heat sink block.

### PRIOR ART DOCUMENT

### Patent Document

Patent Document 1: Japanese Patent Application Laid-Open No. 2003-258166

### SUMMARY

### Problem to be Solved by the Invention

The heat dissipation path formed in the front surface side of the semiconductor element is preferably formed of a component that easily conducts heat and has a large heat capacity. On the other hand, the terminal connected to the front surface electrode of the semiconductor element is preferably a thin plate from the viewpoint of workability and cost. That is, it has been difficult to achieve both high heat dissipation and low production cost.

In order to solve the above problems, the present disclosure provides a semiconductor device having excellent heat dissipation at low cost.

### Means to Solve the Problem

A semiconductor device according to the present disclosure includes a heat spreader, a semiconductor element, a metal block, a terminal, and a sealing material. The semiconductor element includes a front surface electrode. The semiconductor element is mounted on an upper surface of the heat spreader. The metal block includes a bonding surface and at least one heat dissipating surface. The bonding surface is bonded to the front surface electrode of the semiconductor element. The at least one heat dissipating surface is connected to the upper surface of the heat spreader with interposition of the insulating member. The metal block extends from the bonding surface to the at least one heat dissipating surface so as to straddle above at least one side of the semiconductor element. The terminal includes a first end and a second end. The first end is bonded to the metal block. The second end is positioned on the opposite side from the first end and is formed to be connectable to an external circuit. The sealing material seals the heat spreader, the semiconductor element, the metal block, and the first end of the terminal. The second end of the terminal is exposed from the sealing material.

### Effects of the Invention

According to the present disclosure, a semiconductor device having excellent heat dissipation at low cost is provided.

The objects, features, aspects, and advantages of the present disclosure will become more apparent from the following detailed description and the accompanying drawings.

### BRIEF DESCRIPTION OF DRAWINGS

FIG. 1 is a plan view showing a configuration of a semiconductor device in a first embodiment.

FIG. 2 is a cross-sectional view showing a configuration of the semiconductor device in the first embodiment.

FIG. 3 is a plan view showing a configuration of the semiconductor device in the first embodiment.

FIG. 4 is a flowchart showing a method of manufacturing the semiconductor device in the first embodiment.

FIG. 5 is a plan view showing a configuration of a semiconductor device in a second embodiment.

FIG. 6 is a cross-sectional view showing a configuration of the semiconductor device in the second embodiment.

FIG. 7 is a plan view showing a configuration of a semiconductor device in a third embodiment.

FIG. 8 is a cross-sectional view showing a configuration of the semiconductor device in the third embodiment.

FIG. 9 is a plan view showing a configuration of a semiconductor device in a fourth embodiment.

FIG. 10 is a cross-sectional view showing a configuration of the semiconductor device in the fourth embodiment.

FIG. 11 is a plan view showing a configuration of a semiconductor device in a fifth embodiment.

FIG. 12 is a cross-sectional view showing a configuration of the semiconductor device in the fifth embodiment.

FIG. 13 is a plan view showing a configuration of a semiconductor device in a sixth embodiment.

FIG. 14 is a cross-sectional view showing a configuration of the semiconductor device in the sixth embodiment.

FIG. 15 is a plan view showing a configuration of a semiconductor device in a seventh embodiment.

FIG. 16 is a cross-sectional view showing a configuration of the semiconductor device in the seventh embodiment.

### DESCRIPTION OF EMBODIMENTS

### First Embodiment

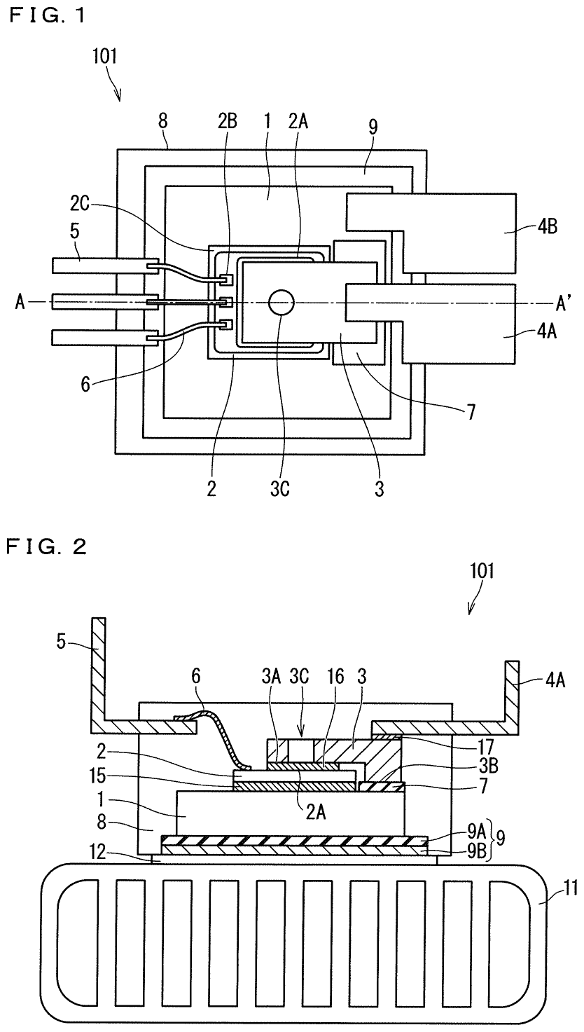

FIG. 1 is a plan view showing a configuration of a semiconductor device 101 in a first embodiment. FIG. 2 is a cross-sectional view showing a configuration of the semiconductor device 101. FIG. 2 shows a cross section taken along line A-A′ shown in FIG. 1.

The semiconductor device 101 includes a heat spreader 1, a semiconductor element 2, a metal block 3, a first main terminal 4A, a second main terminal 4B, a signal terminal 5, a metal wire 6, an insulating member 7, a sealing material 8, and an insulating sheet 9. FIG. 1 shows a state in which the sealing material 8 covering above the semiconductor element 2 or the like is seen through. The same applies to the plan views shown below. FIG. 2 shows a state where the semiconductor device 101 is mounted on a cooler 11 with interposition of a heat dissipating grease 12. In addition, in the cross-sectional view in FIG. 2, hatching of the heat spreader 1 and the sealing material 8 is omitted for convenience of description. The same applies to the cross-sectional views below.

The heat spreader 1 is formed of metal, for example. The heat spreader 1 holds the semiconductor element 2 on its upper surface with interposition of a bonding material 15. The bonding material 15 is, for example, solder.

The semiconductor element 2 is mounted on an upper surface of the heat spreader 1. The semiconductor element 2 is formed of, for example, a semiconductor such as Si, or what is called a wide bandgap semiconductor such as SiC, GaN, or gallium oxide. The semiconductor element 2 is a power semiconductor element, a control integrated circuit (IC) for controlling the power semiconductor element, or the like. The semiconductor element 2 is, for example, an insulated gate bipolar transistor (IGBT), a metal oxide semiconductor field effect transistor (MOSFET), a Schottky barrier diode, or the like. Alternatively, the semiconductor element 2 may be a reverse-conducting IGBT (RC-IGBT) in which an IGBT and a freewheeling diode are formed in one semiconductor substrate.

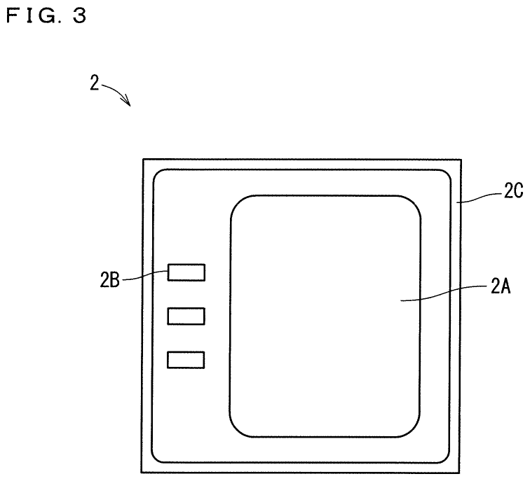

The semiconductor element 2 in the first embodiment is an IGBT. FIG. 3 is a plan view showing a configuration of the semiconductor element 2. The semiconductor element 2 is in a chip state and has a rectangular planar shape. The semiconductor element 2 includes a front surface electrode 2A, a control electrode 2B, and a termination region 2C, on a front surface thereof. A cell region (not shown) in which a plurality of IGBT cells are arrayed is provided inside the termination region 2C. The front surface electrode 2A is an electrode pad that functions as an emitter of the IGBT. The control electrode 2B includes a gate pad, an emitter sense pad, a temperature sense pad, and the like. The gate pad functions as a gate of the IGBT. Since being connected to the signal terminal 5 through the metal wire 6, the control electrode 2B is also referred to as a signal wire pad. The termination region 2C is provided around the cell region, that is, at the outer peripheral portion of the chip. The termination region 2C includes a guard ring being a structure for holding a withstand voltage of the semiconductor element 2. The semiconductor element 2 includes a back surface electrode (not shown) on a back surface thereof. The back surface electrode functions as a collector of the IGBT. The back surface electrode is bonded to the upper surface of the heat spreader 1 with interposition of the bonding material 15. Here, the back surface electrode is bonded to a die pad region (not shown) provided on the upper surface of the heat spreader 1.

The metal block 3 includes a bonding surface 3A and a heat dissipating surface 3B. The bonding surface 3A and the heat dissipating surface 3B are positioned on the lower surface of the metal block 3. The bonding surface 3A is bonded to the front surface electrode 2A of the semiconductor element 2 with interposition of the bonding material 16. The bonding material 16 is, for example, solder. The heat dissipating surface 3B is connected to an upper surface of the heat spreader 1 with interposition of the insulating member 7. More specifically, the heat dissipating surface 3B is in contact with the upper surface of the insulating member 7, and the lower surface of the insulating member 7 is in contact with the upper surface of the heat spreader 1. The metal block 3 extends from the bonding portion between the bonding surface 3A and the front surface electrode 2A of the semiconductor element 2 to the outside of the semiconductor element 2 beyond one side (the right side in FIG. 1) of the semiconductor element 2, and is bent downward. That is, the metal block 3 in the first embodiment has an L-shaped cross-sectional shape and is provided so as to straddle above one side of the semiconductor element 2.

Preferably, the metal block 3 is formed of a material having a high thermal conductivity, and has a large heat capacity. The metal block 3 is preferably formed of, for example, copper or an alloy containing copper. Copper or an alloy containing copper has good bonding property to solder. The metal block 3 formed of copper or an alloy containing copper is excellent in assembling property. The metal block 3 is preferably formed of a material having a linear expansion coefficient of 7 ppm/° C. or more and 12 ppm/° C. or less. The thickness of the metal block 3 is preferably, for example, about 2 mm.

The metal block 3 includes a through hole 3C in the bonding surface 3A. The through hole 3C penetrates between the upper surface and the lower surface of the metal block 3. The through hole 3C is provided approximately at the center of the bonding surface 3A. In other words, in a plan view, the through hole 3C is provided approximately at the center of the bonding portion between the bonding surface 3A and the front surface electrode 2A of the semiconductor element 2.

The insulating member 7 secures a necessary withstand voltage with respect to a voltage applied between the emitter and the collector. The thickness of the insulating member 7 is preferably small so that heat is efficiently transferred from the metal block 3 to the heat spreader 1. That is, the insulating member 7 is preferably thin as long as a withstand voltage is secured.

The first main terminal 4A has a plate shape. The first main terminal 4A includes one end and the other end positioned on the opposite side from the one end. The one end of the first main terminal 4A is bonded to the upper surface of the metal block 3 with interposition of a bonding material 17. The bonding material 17 is, for example, solder. The other end of the first main terminal 4A is led out to the outside of the sealing material 8. The other end of the first main terminal 4A is formed to be connectable to an external circuit. The first main terminal 4A is an emitter connected to the front surface electrode 2A of the semiconductor element 2 with interposition of the metal block 3. The first main terminal 4A has a bent portion between the one end and the other end.

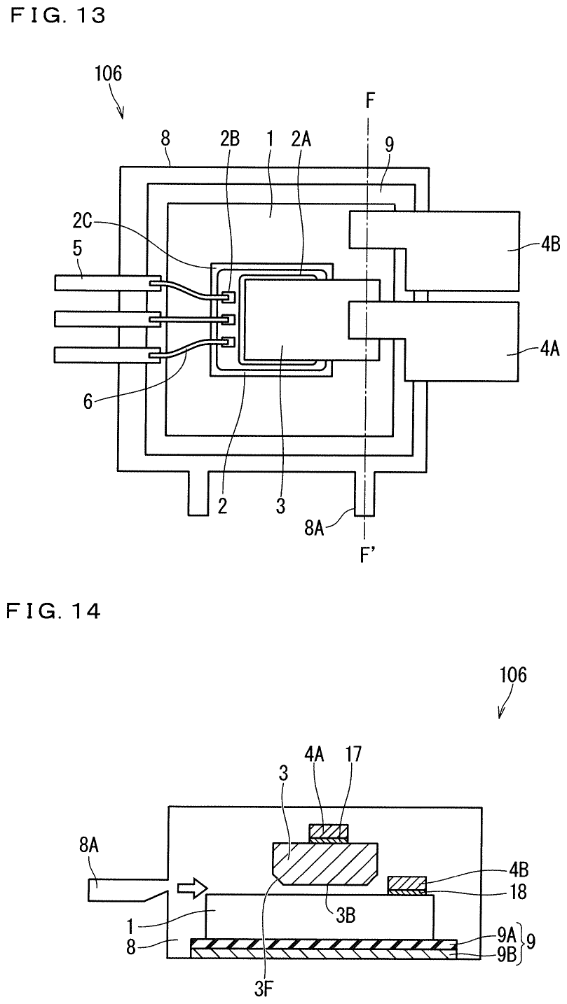

The second main terminal 4B has a plate shape. The second main terminal 4B includes one end and the other end positioned on the opposite side from the one end. The one end of the second main terminal 4B is bonded to the upper surface of the heat spreader 1 with interposition of a bonding material (bonding material 18 shown in FIG. 14). The bonding material 18 is, for example, solder. The other end of the second main terminal 4B is led out to the outside of the sealing material 8. The other end of the second main terminal 4B is formed to be connectable to an external circuit. The second main terminal 4B is a collector connected to the back surface electrode of the semiconductor element 2 with interposition of the heat spreader 1. The second main terminal 4B has a bent portion between the one end and the other end.

The signal terminal 5 has a plate shape. The signal terminal 5 includes one end and the other end positioned on the opposite side from the one end. The one end of the signal terminal 5 is bonded to the control electrode 2B through the metal wire 6. The metal wire 6 is, for example, an aluminum wire. The other end of the signal terminal 5 is led out to the outside of the sealing material 8. The other end of the signal terminal 5 is formed to be connectable to an external circuit. The signal terminal 5 has a bent portion between the one end and the other end.

The first main terminal 4A, the second main terminal 4B, and the signal terminal are preferably formed of, for example, copper or an alloy containing copper. The first main terminal 4A, the second main terminal 4B, and the signal terminal 5 are thinner than the metal block 3. The thicknesses of the first main terminal 4A, the second main terminal 4B, and the signal terminal 5 are preferably, for example, 1 mm or less. Since the first main terminal 4A, the second main terminal 4B, and the signal terminal 5 are thinner than the metal block 3, cutting or bending is easy in the manufacturing step of the semiconductor device 101.

The insulating sheet 9 is attached to a lower surface of the heat spreader 1. The insulating sheet 9 has a configuration in which an insulating layer 9A and a copper foil 9B are integrated. The thickness of the insulating layer 9A is about 0.2 mm. The thickness of the copper foil 9B is about 0.1 mm.

The sealing material 8 seals the heat spreader 1, the semiconductor element 2, the metal block 3, the one end of the first main terminal 4A, the one end of the second main terminal 4B, the metal wire 6, the one end of the signal terminal 5, and the upper surface side of the insulating sheet 9. The lower surface of the copper foil 9B of the insulating sheet 9, the other end of the first main terminal 4A, the other end of the second main terminal 4B, and the other end of the signal terminal 5 are exposed from the sealing material 8. The sealing material 8 is, for example, a mold resin. In the IGBT for power control, a high voltage is applied between the emitter and the collector. The withstand voltage of the IGBT is secured by the mold resin and the guard ring of the termination region 2C.

The cooler 11 is attached to the semiconductor device 101 with interposition of the heat dissipating grease 12. The heat dissipating grease 12 fills a minute space that can be generated between the copper foil 9B of the insulating sheet 9 and the cooler 11. The heat dissipating grease 12 makes heat transfer between the insulating sheet 9 and the cooler 11 easier. The cooler 11 releases heat generated in the semiconductor element 2 to the outside.

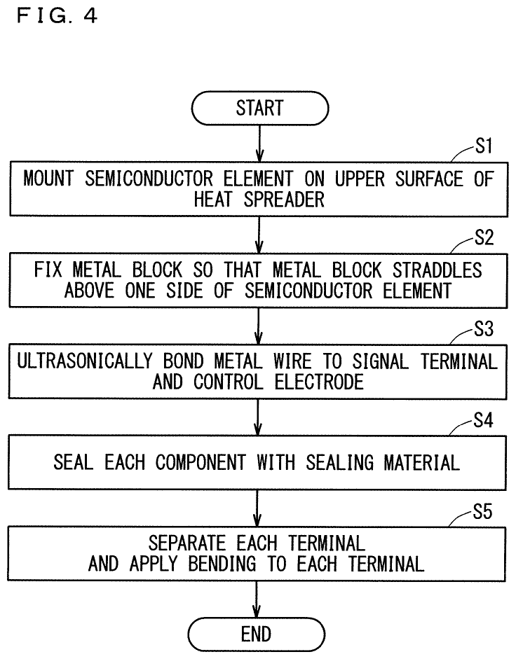

Next, a method of manufacturing the semiconductor device 101 in the first embodiment will be described. FIG. 4 is a flowchart showing a method of manufacturing the semiconductor device 101.

In step S1, the semiconductor element 2 is mounted on the upper surface of the heat spreader 1 with interposition of the bonding material 15.

In step S2, the metal block 3 is placed at a predetermined position with respect to the semiconductor element 2 and the heat spreader 1. At this time, the position of the bonding surface 3A of the metal block 3 is adjusted to above the front surface electrode 2A of the semiconductor element 2. More specifically, in a plan view, the position of the through hole 3C of the metal block 3 is adjusted to the vicinity of the center of the front surface electrode 2A of the semiconductor element 2. The position of the heat dissipating surface 3B of the metal block 3 is adjusted to above the insulating member 7 provided on the upper surface of the heat spreader 1. The insulating member 7 may be provided at a predetermined position on the upper surface of the heat spreader 1 in advance, or may be inserted into between the metal block 3 and the heat spreader 1 in step S2. Similarly, the lead frame in which the first main terminal 4A, the second main terminal 4B, and the signal terminal 5 are integrated is placed at a predetermined position with respect to the metal block 3 and the heat spreader 1. A jig is used to position each component. When the positional relationship between the metal block 3 and the semiconductor element 2 is temporarily fixed by the jig, a gap is formed between the bonding surface 3A of the metal block 3 and the front surface electrode 2A of the semiconductor element 2.

After each component is positioned, each bonding place in the heat spreader 1, the semiconductor element 2, the metal block 3, and the lead frame is bonded by a bonding material. That is, the metal block 3 is bonded to the semiconductor element 2 by the bonding material 16, the first main terminal 4A is bonded to the metal block 3 by the bonding material 17, and the second main terminal 4B is bonded to the heat spreader 1 by the bonding material 18. In the bonding step between the metal block 3 and the semiconductor element 2, the melted bonding material 16 is supplied from the through hole 3C. The bonding material 16 spreads in a gap between the bonding surface 3A and the front surface electrode 2A. The bonding material 16 is, for example, solder. Accordingly, the metal block 3 is fixed so as to straddle above one side of the semiconductor element 2.

In step S3, the metal wire 6 is ultrasonically bonded to the signal terminal 5 and the control electrode 2B. This step is what is called a wire bonding step.

In step S4, the heat spreader 1, the semiconductor element 2, the metal block 3, the one end of the first main terminal 4A, the one end of the second main terminal 4B, the metal wire 6, the one end of the signal terminal 5, and the upper surface side of the insulating sheet 9 are set in the cavity of the molding mold. Resin pellets are set in a pot. The molten resin is extruded from the pot into the heated mold by the plunger. The resin passes through the runner and flows into the cavity through the injection gate of the mold. Thereafter, the resin is cured, and the heat spreader 1, the semiconductor element 2, the metal block 3, the one end of the first main terminal 4A, the one end of the second main terminal 4B, the metal wire 6, the one end of the signal terminal 5, and the upper surface side of the insulating sheet 9 are sealed. The resin corresponds to the sealing material 8.

In step S5, unnecessary resin cured at the injection gate portion is cut off, and a package is formed. Furthermore, coupling portions of the lead frame are cut, and the first main terminal 4A, the second main terminal 4B, and the signal terminal 5 are separated from each other. Each of the first main terminal 4A, the second main terminal 4B, and the signal terminal 5 is subjected to bending into a predetermined shape. Thus, the semiconductor device 101 is completed.

Next, the operation of the semiconductor device 101 in the first embodiment will be described. Each of the other end of the first main terminal 4A and the other end of the second main terminal 4B is connected to a bus bar (not shown).

When a voltage is applied from the signal terminal 5 to between the gate and the emitter of the IGBT through the gate pad, the IGBT is driven. That is, the current flows from the bus bar on the collector side to the second main terminal 4B, the heat spreader 1, the semiconductor element 2, the metal block 3, the first main terminal 4A, and the bus bar on the emitter side in order. At that time, heat is generated by the internal resistance of the semiconductor element 2. The semiconductor device 101 in the first embodiment not only releases the heat from the back surface of the semiconductor element 2 to the cooler 11 with interposition of the heat spreader 1, the insulating sheet 9, and the heat dissipating grease 12, but also releases the heat from the front surface of the semiconductor element 2 to the cooler 11 with interposition of the metal block 3, the insulating member 7, the heat spreader 1, the insulating sheet 9, and the heat dissipating grease 12.

Since the metal block 3 has a function of transferring heat and a function of storing heat, the metal block 3 is preferably formed of a material having high thermal conductivity, and the heat capacity of the metal block 3 is preferably large. Therefore, the metal block 3 is preferably thick. On the other hand, since being subjected to cutting or bending in the manufacturing step of the semiconductor device 101, the first main terminal 4A is preferably thinner than the metal block 3. When the metal block 3 and the first main terminal 4A constitute an integrated component, the integrated component has a thicker portion and a thinner portion. That is, since the component has a special and complicated shape, the production cost increases. On the other hand, when the semiconductor device does not include the metal block 3, heat generated in the semiconductor element 2 is also released through the first main terminal 4A having a thin plate shape, but a sufficient heat dissipation effect cannot be expected.

The metal block 3 and the first main terminal 4A in the first embodiment are components separate from each other. The semiconductor device 101 includes a metal block 3 thicker than the first main terminal 4A in order to increase heat capacity, and includes a first main terminal 4A thinner than the metal block 3 in order to improve workability. Therefore, both high heat dissipation and low production costs are achieved.

An electric motor car such as an electric vehicle or a hybrid vehicle is provided with an inverter circuit. The inverter circuit that drives the three-phase motor has a configuration in which six semiconductor devices 101 are combined. The inverter circuit controls the rotation speed and the like of the three-phase motor by pulse width modulation (PWM) control. The motor may be temporarily locked, such as when the electric motor car climbs on a curb. At this time, a large current flows through the semiconductor element 2. Although the time during which the large current flows is a short time of about 1 second or less, the amount of heat generated in the semiconductor element 2 is large.

In the semiconductor device 101 in the first embodiment, the heat is not only released from the back surface of the semiconductor element 2 to the cooler 11 with interposition of the heat spreader 1, the insulating sheet 9, and the heat dissipating grease 12, but also released from the front surface of the semiconductor element 2 to the cooler 11 with interposition of the metal block 3, the insulating member 7, the heat spreader 1, the insulating sheet 9, and the heat dissipating grease 12. Therefore, high heat dissipation is achieved.

In summary, the semiconductor device 101 in the first embodiment includes the heat spreader 1, the semiconductor element 2, the metal block 3, the first main terminal 4A, and the sealing material 8. The semiconductor element 2 includes the front surface electrode 2A. The semiconductor element 2 is mounted on the upper surface of the heat spreader 1. The metal block 3 includes the bonding surface 3A and at least one heat dissipating surface 3B. The bonding surface 3A is bonded to the front surface electrode 2A of the semiconductor element 2. The at least one heat dissipating surface 3B is connected to the upper surface of the heat spreader 1 with interposition of the insulating member 7. The metal block 3 extends from the bonding surface 3A to the at least one heat dissipating surface 3B so as to straddle above at least one side of the semiconductor element 2. The first main terminal 4A includes a first end and a second end. The first end is bonded to the metal block 3. The second end is positioned on the opposite side from the first end and is formed to be connectable to an external circuit. The sealing material 8 seals the heat spreader 1, the semiconductor element 2, the metal block 3, and the first end of the first main terminal 4A. The second end of the first main terminal 4A is exposed from the sealing material 8.

This semiconductor device 101 achieves both high heat dissipation and low production cost. The semiconductor device 101 is used for an inverter circuit that controls a motor of an electric vehicle, a train, or the like, or a converter circuit for regeneration.

In addition, the metal block 3 in the first embodiment includes a through hole 3C in the bonding surface 3A. When the metal block 3 is formed of copper or an alloy containing copper, and the semiconductor element 2 is formed of Si, a difference between the linear expansion coefficient of the metal block 3 and the linear expansion coefficient of the semiconductor element 2 is large. When the reflow step is applied to the bonding between the metal block 3 and the semiconductor element 2, stress associated with temperature change is large. The thickness of the solder changes before and after the reflow step regardless of whether the bonding material 16 is plate-shaped solder or cream-shaped solder. In the first embodiment, molten solder is supplied from the through hole 3C of the metal block 3. Therefore, the thickness of the bonding material 16 matches the width of the gap, and is controlled to a constant value. Therefore, the semiconductor device 101 having high reliability is implemented.

Furthermore, when the metal block 3 is formed of a material having a linear expansion coefficient of 7 ppm/° C. or more and 12 ppm/° C. or less, stress on the chip at the time of heating in a bonding step or the like is reduced. Therefore, the reliability of the semiconductor device 101 is improved.

When the semiconductor element 2 is formed of SiC having a high thermal conductivity, heat dissipation is improved, so that the size of the semiconductor element 2 can be reduced.

### Second Embodiment

A semiconductor device and a method of manufacturing the semiconductor device in a second embodiment will be described. In the second embodiment, the same components as those of the first embodiment are denoted by the same reference numerals, and the detailed description thereof will be omitted.

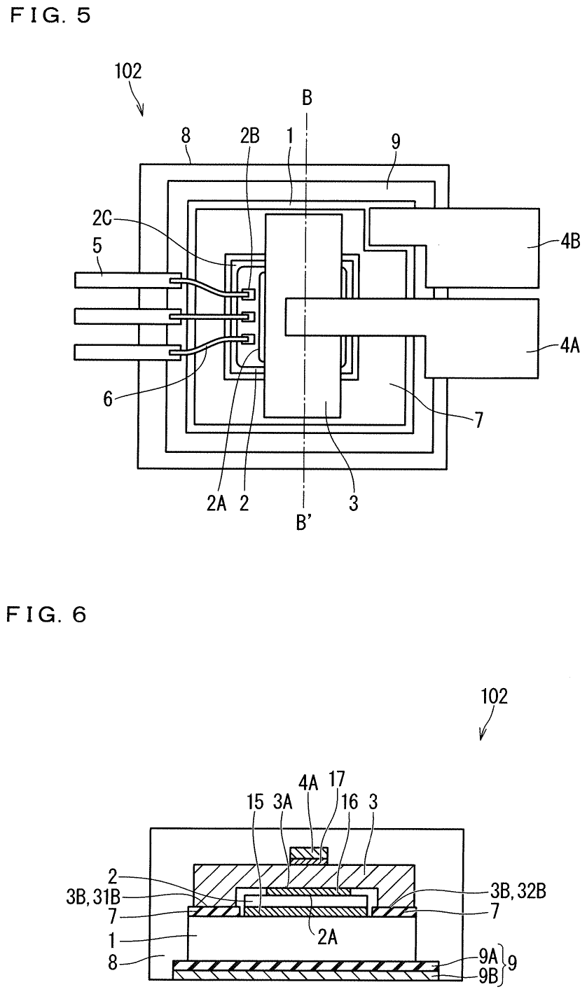

FIG. 5 is a plan view showing a configuration of a semiconductor device 102 in the second embodiment. FIG. 6 is a cross-sectional view showing a configuration of the semiconductor device 102. FIG. 6 shows a cross section taken along line B-W shown in FIG. 5.

The metal block 3 includes a plurality of heat dissipating surfaces 3B. The plurality of heat dissipating surfaces 3B are positioned on the lower surface of the metal block 3. Here, the metal block 3 includes a first heat dissipating surface 31B and a second heat dissipating surface 32B. Each of the first heat dissipating surface 31B and the second heat dissipating surface 32B is connected to an upper surface of the heat spreader 1 with interposition of the insulating member 7. The bonding surface 3A of the metal block 3 is positioned between the first heat dissipating surface 31B and the second heat dissipating surface 32B.

The metal block 3 extends from the bonding portion between the bonding surface 3A and the front surface electrode 2A of the semiconductor element 2 to the outside of the semiconductor element 2 beyond a first side (the upper side in FIG. 5) of the semiconductor element 2, and is bent downward. A lower surface of the downward bent portion is the first heat dissipating surface 31B. The metal block 3 extends from the bonding portion to the outside of the semiconductor element 2 beyond a second side (the lower side in FIG. 5) opposite to the first side of the semiconductor element 2, and is bent downward. A lower surface of the bent portion is the second heat dissipating surface 32B. The metal block 3 in the second embodiment has a U-shaped cross-sectional shape and is provided so as to straddle above two sides of the semiconductor element 2.

The insulating member 7 is an insulating resin film formed on an upper surface of the heat spreader 1. The insulating resin film is formed in a region excluding a die pad region to which the back surface electrode of the semiconductor element 2 is bonded and a terminal bonding region (not shown) to which the second main terminal 4B is bonded.

The method of manufacturing the semiconductor device 102 in the second embodiment is similar to the method of manufacturing the semiconductor device in the first embodiment. However, in step S1, a heat spreader 1 coated with the insulating resin film in advance in a region excluding the die pad region and the terminal bonding region is prepared. The semiconductor element 2 is mounted on the die pad region of the heat spreader 1. At this time, since the die pad region is surrounded by the insulating resin film, the solder does not flow out to the periphery of the die pad region. In step S2, the bonding surface 3A of the metal block 3 is bonded to the front surface electrode 2A of the semiconductor element 2, and the first heat dissipating surface 31B and the second heat dissipating surface 32B are connected to the heat spreader 1 with interposition of the insulating resin film.

In this semiconductor device 102, since the metal block 3 has the plurality of heat dissipating surfaces 3B, heat dissipation is improved. For example, the chip temperature distribution of the IGBT is leveled.

Since the heat dissipating surface 3B of the metal block 3 is close to the upper surface of the heat spreader 1 with interposition of the thin insulating resin film, favorable heat dissipation is obtained. Furthermore, since the thickness of the insulating resin film has high uniformity, uniform heat dissipation is achieved on each heat dissipating surface 3B. Since it is not necessary to insert the insulating member 7 as in the first embodiment, productivity is improved.

In the second embodiment, an example of the semiconductor device 102 in which the metal block 3 extends to the outside of the two sides of the semiconductor element 2 has been shown. The metal block 3 may extend to the outside of the three sides of the semiconductor element 2. By providing three heat dissipating surfaces 3B, heat dissipation is further improved.

### Third Embodiment

A semiconductor device and a method of manufacturing the semiconductor device in a third embodiment will be described. In the third embodiment, the same components as those of the first or second embodiment are denoted by the same reference numerals, and the detailed description thereof will be omitted.

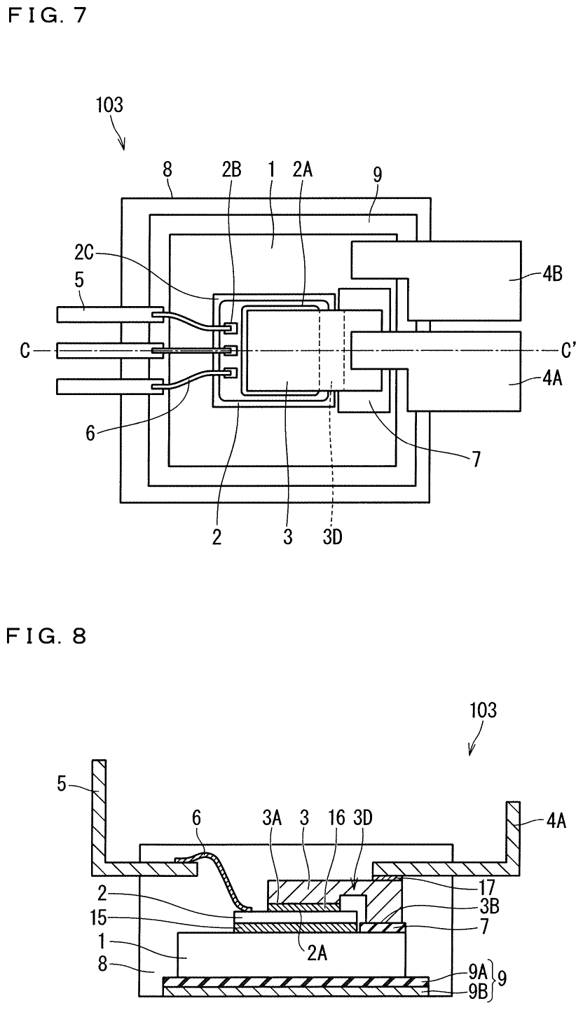

FIG. 7 is a plan view showing a configuration of a semiconductor device 103 in the third embodiment. FIG. 8 is a cross-sectional view showing a configuration of the semiconductor device 103. FIG. 8 shows a cross section taken along line C-C′ shown in FIG. 7.

The metal block 3 includes a recessed portion 3D. The recessed portion 3D is provided on the lower surface of the metal block 3. The recessed portion 3D is recessed in the direction from the lower surface to the upper surface of the metal block 3 with respect to the bonding surface 3A.

The recessed portion 3D is provided outside a bonding portion where the bonding surface 3A and the front surface electrode 2A of the semiconductor element 2 are bonded. The recessed portion 3D in the third embodiment is a groove provided above the termination region 2C of the semiconductor element 2, that is, above the guard ring. The extending direction of the groove corresponds to the extending direction of the guard ring.

The method of manufacturing the semiconductor device 103 is similar to the method of manufacturing the semiconductor device in the first embodiment. In step S4, when the resin is injected into the mold, the groove of the metal block 3 improves the fluidity of the resin above the guard ring. Therefore, the generation of air bubbles is suppressed, and the insulation property is improved. This semiconductor device 103 prevents a decrease in the withstand voltage of the guard ring.

### Fourth Embodiment

A semiconductor device and a method of manufacturing the semiconductor device in a fourth embodiment will be described. In the fourth embodiment, the same components as those of any one of the first to third embodiments are denoted by the same reference numerals, and the detailed description thereof will be omitted.

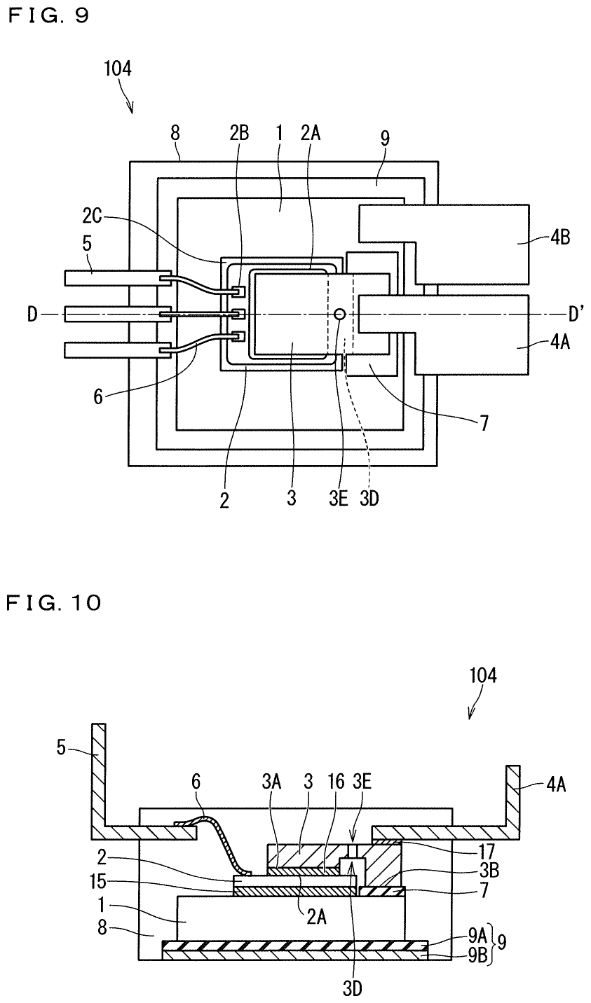

FIG. 9 is a plan view showing a configuration of a semiconductor device 104 in the fourth embodiment. FIG. 10 is a cross-sectional view showing a configuration of the semiconductor device 104. FIG. 10 shows a cross section taken along line D-D′ shown in FIG. 9.

As in the third embodiment, the metal block 3 includes a groove provided above the guard ring as the recessed portion 3D. The metal block 3 in the fourth embodiment includes a hole 3E penetrating between the bottom portion of the groove and the upper surface of the metal block 3.

The method of manufacturing the semiconductor device 104 is similar to the method of manufacturing the semiconductor device in the first embodiment. In step S4, when the resin is injected into the mold, air bubbles easily escape from the hole 3E. This semiconductor device 104 prevents a decrease in the withstand voltage of the guard ring.

### Fifth Embodiment

A semiconductor device and a method of manufacturing the semiconductor device in a fifth embodiment will be described. In the fifth embodiment, the same components as those of any one of the first to fourth embodiments are denoted by the same reference numerals, and the detailed description thereof will be omitted.

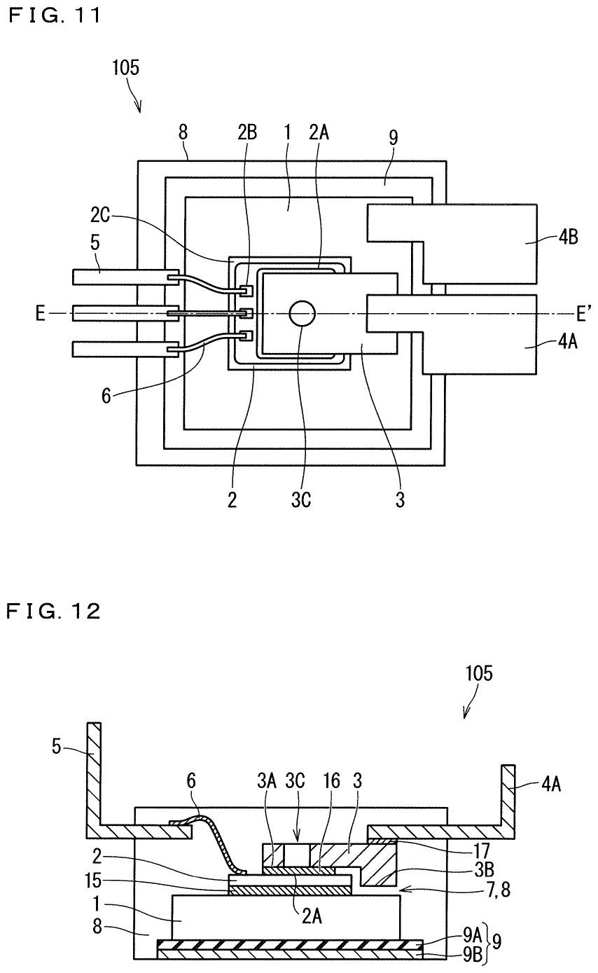

FIG. 11 is a plan view showing a configuration of a semiconductor device 105 in the fifth embodiment. FIG. 12 is a cross-sectional view showing a configuration of the semiconductor device 105. FIG. 12 shows a cross section taken along line E-E′ shown in FIG. 11.

The insulating member 7 between the upper surface of the heat spreader 1 and the heat dissipating surface 3B of the metal block 3 is a sealing material 8. That is, the insulating member 7 is formed of a molding resin. In order to improve heat dissipation from the metal block 3 to the heat spreader 1, it is preferable that the molding resin between the heat dissipating surface 3B and the heat spreader 1 is thin as long as a necessary withstand voltage is secured.

The method of manufacturing the semiconductor device 105 is similar to the method of manufacturing the semiconductor device in the first embodiment. However, in step S2, the metal block 3 and the like are bonded in a state where a gap is formed between the upper surface of the heat spreader 1 and the heat dissipating surface 3B of the metal block 3. That is, after completion of step S2, the insulating member 7 is not present between the upper surface of the heat spreader 1 and the heat dissipating surface 3B of the metal block 3. In step S4, resin is flowed into the gap between the heat dissipating surface 3B of the metal block 3 and the upper surface of the heat spreader 1, and the insulating member 7 is formed.

The molding resin injected into the gap between the heat dissipating surface 3B of the metal block 3 and the upper surface of the heat spreader 1 achieves both an insulating function between the metal block 3 and the heat spreader 1 and a heat dissipation function from the metal block 3 to the heat spreader 1. Since the insulating member 7 shown in the first embodiment and the insulating resin film shown in the second embodiment are unnecessary, cost reduction is achieved.

### Sixth Embodiment

A semiconductor device and a method of manufacturing the semiconductor device in a sixth embodiment will be described. In the sixth embodiment, the same components as those of any one of the first to fifth embodiments are denoted by the same reference numerals, and the detailed description thereof will be omitted.

FIG. 13 is a plan view showing a configuration of a semiconductor device 106 in the sixth embodiment. FIG. 14 is a cross-sectional view showing a configuration of the semiconductor device 106. FIG. 14 shows a cross section taken along line F-F′ shown in FIG. 13. The method of manufacturing the semiconductor device 106 is similar to the method of manufacturing the semiconductor device in the first embodiment. In step S5, the resin is injected from the two injection gates 8A. FIGS. 13 and 14 show the semiconductor device 106 in a state before the resin cured in the injection gates 8A is cut off.

The metal block 3 has inclined surfaces 3F at end portions of the heat dissipating surface 3B.

In step S4 of the method of manufacturing the semiconductor device 106, the injection gates 8A for injecting the resin are provided in the lateral direction of the gap between the heat dissipating surface 3B of the metal block 3 and the upper surface of the heat spreader 1. The height of the injection gates 8A approximately matches the height of the upper surface of the heat spreader 1. The resin is filled into the cavity of the mold through the injection gates 8A.

In order to efficiently transfer heat from the heat dissipating surface 3B of the metal block 3 to the heat spreader 1, it is preferable that the gap between the heat dissipating surface 3B and the upper surface of the heat spreader 1 is narrow. However, since the resin has viscosity, it is difficult to fill a narrow space. When the gap is too narrow, the gap is not filled with the resin, and the collector and the emitter of the IGBT are short-circuited. In the sixth embodiment, the injection gates 8A are provided at substantially the same height as the upper surface of the heat spreader 1. The resin injected from the injection gates 8A flows along the upper surface of the heat spreader 1, is further guided by the inclined surface 3F of the metal block 3, and the gap is efficiently filled with the resin. As a result, the semiconductor device 106 that achieves both securing of insulation property and improvement in heat dissipation is implemented. Even when the metal block 3 includes a curved surface instead of the inclined surface 3F, a similar effect is produced.

### Seventh Embodiment

A semiconductor device and a method of manufacturing the semiconductor device in a seventh embodiment will be described. In the seventh embodiment, the same components as those of any one of the first to sixth embodiments are denoted by the same reference numerals, and the detailed description thereof will be omitted.

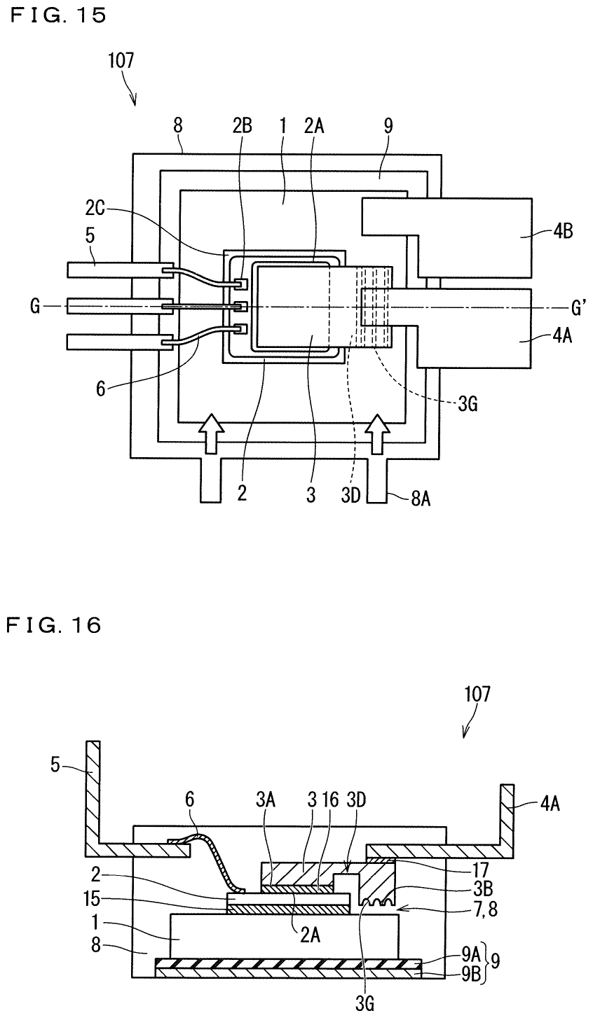

FIG. 15 is a plan view showing a configuration of a semiconductor device 107 in the seventh embodiment. FIG. 16 is a cross-sectional view showing a configuration of the semiconductor device 107. FIG. 16 shows a cross section taken along line G-G′ shown in FIG. 15. As in the sixth embodiment, FIG. 15 shows the semiconductor device 107 in a state before the resin cured in the injection gates 8A is cut off.

The metal block 3 includes a plurality of narrow grooves 3G on the heat dissipating surface 3B. The extending direction of the stripe-shaped narrow groove 3G is a direction from the injection gate 8A toward the gap between the heat dissipating surface 3B of the metal block 3 and the upper surface of the heat spreader 1. In other words, the injection gate 8A is provided at a destination where the narrow groove 3G extends. Since the resin injected from the injection gate 8A is filled along the stripe-shaped narrow groove 3G, the filling property is further improved.

In the present disclosure, each embodiment can be freely combined, and each embodiment can be appropriately modified or omitted.

### EXPLANATION OF REFERENCE SIGNS

1: heat spreader
2: semiconductor element
2A: front surface electrode
2B: control electrode
2C: termination region
3: metal block
3A: bonding surface
3B: heat dissipating surface
3C: through hole
3D: recessed portion
3E: hole
3F: inclined surface
3G: narrow groove
4A: first main terminal
4B: second main terminal
5: signal terminal
6: metal wire
7: insulating member
8: sealing material
8A: injection gate
9: insulating sheet
9A: insulating layer
9B: copper foil
11: cooler
12: heat dissipating grease
15: bonding material
16: bonding material
17: bonding material
31B: first heat dissipating surface
32B: second heat dissipating surface
101 to 107: semiconductor device

1. A semiconductor device comprising:
a heat spreader;
a semiconductor element including a front surface electrode, the semiconductor element mounted on an upper surface of the heat spreader;
a metal block including a bonding surface bonded to the front surface electrode of the semiconductor element and at least one heat dissipating surface connected to the upper surface of the heat spreader with interposition of an insulating member, the metal block extending from the bonding surface to the at least one heat dissipating surface so as to straddle above at least one side of the semiconductor element;
a terminal including a first end bonded to the metal block and a second end positioned on an opposite side from the first end and formed to be connectable to an external circuit; and
a sealing material sealing the heat spreader, the semiconductor element, the metal block, and the first end of the terminal,
wherein the second end of the terminal is exposed from the sealing material.

2. The semiconductor device according to claim 1, wherein the metal block includes a through hole in the bonding surface.

3. The semiconductor device according to claim 1, wherein the insulating member is an insulating resin film provided on the upper surface of the heat spreader.

4. The semiconductor device according to claim 1, wherein
the at least one heat dissipating surface is a plurality of heat dissipating surfaces,
the bonding surface is positioned between the plurality of heat dissipating surfaces and is bonded to the front surface electrode, and
the metal block extends from the bonding surface to the plurality of heat dissipating surfaces so as to straddle above a plurality of sides of the semiconductor element.

5. The semiconductor device according to claim 1, wherein
the metal block includes a recessed portion outside a bonding portion in which the bonding surface and the front surface electrode are bonded, and
the recessed portion is recessed in a direction from a lower surface of the metal block toward the upper surface with respect to the bonding surface.

6. The semiconductor device according to claim 5, wherein the metal block includes a hole penetrating between a bottom portion of the recessed portion and the upper surface of the metal block.

7. The semiconductor device according to claim 1, wherein the metal block is formed of a material having a linear expansion coefficient of 7 ppm/° C. or more and 12 ppm/° C. or less.

8. The semiconductor device according to claim 1, wherein the semiconductor element is formed of SiC.

9. A semiconductor device comprising:
a heat spreader;
a semiconductor element including a front surface electrode, the semiconductor element mounted on an upper surface of the heat spreader;
a metal block including a bonding surface bonded to the front surface electrode of the semiconductor element and at least one heat dissipating surface connected to the upper surface of the heat spreader with interposition of an insulating member, the metal block extending from the bonding surface to the at least one heat dissipating surface so as to straddle above at least one side of the semiconductor element; and
a sealing material sealing the heat spreader, the semiconductor element, and the metal block,
wherein the insulating member is the sealing material.

10. The semiconductor device according to claim 9, wherein
the metal block includes a plurality of narrow grooves in the heat dissipating surface, and
extending directions of the plurality of narrow grooves are unidirectionally aligned.

11. The semiconductor device according to claim 9, wherein the metal block has an inclined surface or a curved surface at an end portion of the heat dissipating surface.

12. The semiconductor device according to claim 9, wherein the metal block is formed of a material having a linear expansion coefficient of 7 ppm/° C. or more and 12 ppm/° C. or less.

13. The semiconductor device according to claim 9, wherein the semiconductor element is formed of SiC.

14. A method of manufacturing a semiconductor device, the method comprising:
mounting a semiconductor element on an upper surface of a heat spreader; and
fixing a metal block so as to straddle above at least one side of the semiconductor element,
wherein the fixing of the metal block includes:
bonding a bonding surface of the metal block to a front surface electrode of the semiconductor element; and
connecting a heat dissipating surface of the metal block to the upper surface of the heat spreader with interposition of an insulating member,
the connecting of the heat dissipating surface of the metal block includes injecting a sealing material for sealing the heat spreader, the semiconductor element, and the metal block as the insulating member into a gap between the heat dissipating surface of the metal block and the upper surface of the heat spreader, and
the sealing material is injected through an injection gate provided in a lateral direction of the gap between the heat dissipating surface of the metal block and the upper surface of the heat spreader.

15. The method of manufacturing a semiconductor device according to claim 14, wherein a height of the injection gate matches a height of the upper surface of the heat spreader.

16. The method of manufacturing a semiconductor device according to claim 14, wherein
the metal block includes a plurality of narrow grooves in the heat dissipating surface, and
extending directions of the plurality of narrow grooves are a direction from the injection gate toward the gap.
